(19) United States
(12) Patent Application Publication
(10) Pub. No.: US 2026/0164883 A1
(43) Pub. Date: Jun. 11, 2026

(54) DISPLAY DEVICE, ELECTRONIC DEVICE AND METHOD FOR FABRICATING THE DISPLAY DEVICE

(71) Applicant: Samsung Display Co., LTD., Yongin-si (KR)

(72) Inventors: Young Seok BAEK, Yongin-si (KR); Yong Han LEE, Yongin-si (KR)

(21) Appl. No.: 19/300,090

(22) Filed: Aug. 14, 2025

(30) Foreign Application Priority Data
Dec. 11, 2024 (KR) 10-2024-0183230

(51) Int. Cl. H10H 29/37; H10H 29/01; H10H 29/39; H10K 59/12; H10K 59/122; H10K 59/123; H10K 77/10; H10K 102/00

(52) U.S. Cl. CPC H10H 29/37; H10H 29/012; H10H 29/39; H10K 59/1201; H10K 59/122; H10K 59/123; H10K 77/111; H10K 2102/311

(57) ABSTRACT

There is provided a display device. The display device includes a substrate including an emission area and a non-emission area; a bank structure located on a surface of the substrate, overlapping with the emission area, and having an overhang structure; a first element insulating layer disposed on the bank structure; a first anode electrode disposed on the first element insulating layer; and a second element insulating layer covering an edge of the first anode electrode, defining an opening, and in contact with the first element insulating layer. An upper surface of the first anode electrode is spaced apart from the second element insulating layer in the non-emission area, and an undercut is formed between the first anode electrode and the second element insulating layer.

This application claims priority to Korean Patent Application No. 10-2024-0183230, filed on Dec. 11, 2024, and all the benefits accruing therefrom under 35 U.S.C. § 119, the content of which in its entirety is herein incorporated by reference.

### BACKGROUND

### 1. Field

The present disclosure relates to a display device, an electronic device using the display device, and a method for fabricating a display device.

### 2. Description of the Related Art

As the information-oriented society evolves, the demand for display devices is ever increasing. For example, display devices are being employed in a variety of electronic devices such as, for example, smart phones, digital cameras, laptop computers, navigation devices, and smart televisions. Display devices may be flat panel display devices such as, for example, a liquid-crystal display device, a field emission display device, and an organic light-emitting display device. Among such flat panel display devices, a light-emitting display device includes a light-emitting element that can emit light on its own, such that each of the pixels of the display panel can emit light by themselves. Accordingly, a light-emitting display device can display images without a backlight unit that supplies light to the display panel.

### SUMMARY

Aspects of the present disclosure provide a display device that can provide high-resolution images, an electronic device using the display device, and a method for fabricating the display device.

Aspects of the present disclosure also provide a display device that can address the problem of damage to an anode electrode and the reliability issue due to moisture permeation.

It should be noted that objects of the present disclosure are not limited to the above-mentioned object; and other objects of the present disclosure will be apparent to those skilled in the art from the following descriptions.

In an embodiment of the disclosure, a display device includes a substrate including an emission area and a non-emission area; a bank structure located on a surface of the substrate, overlapping with the emission area, and having an overhang structure; a first element insulating layer disposed on the bank structure; a first anode electrode disposed on the first element insulating layer; and a second element insulating layer covering an edge of the first anode electrode, defining an opening, and in contact with the first element insulating layer, wherein an upper surface of the first anode electrode is spaced apart from the second element insulating layer in the non-emission area, and an undercut is formed between the first anode electrode and the second element insulating layer.

In an embodiment, the bank structure may include a first bank layer; a second bank layer located on the first bank layer; and a third bank layer having a tip protruding toward the non-emission area more than a side surface of the second bank layer.

In an embodiment, the display device may further include a first emissive layer disposed on the first anode electrode and entirely covering the second element insulating layer; and a first cathode electrode disposed on the first emissive layer and in contact with the tip of the third bank layer.

In an embodiment, the first cathode electrode may be electrically connected to the second bank layer and the first bank layer through the third bank layer.

In an embodiment, the display device may further include a residual pattern which is located between the upper surface of the first anode electrode and the second element insulating layer in a direction perpendicular to the surface of the substrate in the non-emission area.

In an embodiment, the residual pattern may be in contact with the first anode electrode and the second element insulating layer.

In an embodiment, the residual pattern may be completely surrounded by the first emissive layer, the first anode electrode, and the second element insulating layer.

In an embodiment, the residual pattern may surround the opening, and the residual pattern includes a transparent metal material.

In an embodiment, the display device may further include a transistor disposed on the substrate; and a connection electrode disposed on the transistor and electrically connected to the transistor, wherein the first anode electrode and the connection electrode are in contact with each other in an anode contact hole penetrating the bank structure, and the residual pattern surrounds the anode contact hole.

In an embodiment, the display device may further include a cavity which is formed between the upper surface of the first anode electrode and the second element insulating layer in a direction perpendicular to the surface of the substrate in the non-emission area.

In an embodiment, a method for fabricating a display device, the method including: forming an anode electrode, a temporary layer and an element insulating layer on a substrate including a bank structure; performing a dry etching process which forms an opening defined by the element insulating layer; performing a wet etching process which removes the temporary layer and forms a tip of the bank structure; and forming an emissive layer, a cathode electrode and an element inorganic layer on the anode electrode.

In an embodiment, the performing the dry etching process which forms the opening defined by the element insulating layer may include completely covering the anode electrode with the temporary layer in the opening.

In an embodiment, the performing the wet etching process which removes the temporary layer and forms the tip of the bank structure may include completely removing the temporary layer in the opening, wherein a part of the temporary layer outside the opening remains as a residual pattern between the anode electrode and the element insulating layer.

In an embodiment, the performing the wet etching process which removes the temporary layer and forms the tip of the bank structure may include completely removing the temporary layer, wherein a cavity may be formed between the anode electrode and the element insulating layer outside the opening based on the performing the wet etching process.

In an embodiment of the disclosure, an electronic device include at least one display device including a substrate including an emission area and a non-emission area; and at least one of a display module, a processor, a memory, and a power module connected to the at least one display device, wherein the at least one display device includes: a substrate including an emission area and a non-emission area; a bank structure located on a surface of the substrate, overlapping with the emission area, and having an overhang structure; a first element insulating layer disposed on the bank structure; a first anode electrode disposed on the first element insulating layer; and a second element insulating layer covering an edge of the first anode electrode, defining an opening, and in contact with the first element insulating layer, wherein an upper surface of the first anode electrode is spaced apart from the second element insulating layer in the non-emission area, and an undercut is formed between the first anode electrode and the second element insulating layer.

The details of one or more embodiments of the subject matter described in this specification are set forth in the accompanying drawings and the description below.

According to embodiments of the present disclosure, a display device can provide high-resolution images, and it is possible to address the problem of damage to an anode electrode and the reliability issue due to moisture permeation.

It should be noted that effects of the present disclosure are not limited to those described herein and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment of the present disclosure.

FIG. 2 is a cross-sectional view illustrating a display device according to an embodiment of the present disclosure.

FIG. 3 is a plan view illustrating a display layer of a display device according to an embodiment of the present disclosure.

FIG. 4 is a plan view illustrating a plurality of pixels arranged in the display area of FIG. 3.

FIG. 5 is a cross-sectional view illustrating an example of the display layer, taken along line A1-A1′ of FIG. 4.

FIG. 6 is an enlarged, cross-sectional view of the display element layer in the first emission area in FIG. 5.

FIG. 7 is a cross-sectional view illustrating an example of the display layer, taken along line A3-A3′ of FIG. 7.

FIG. 8 is an enlarged, cross-sectional view of the display element layer in the first emission area in FIG. 7.

FIG. 9 is a cross-sectional view illustrating another example of the display layer, taken along line A1-A1′ of FIG. 4.

FIG. 10 is a flowchart for illustrating a method for fabricating the display element layer in FIG. 7.

FIGS. 11 to 13 are cross-sectional views for illustrating step S100 of FIG. 10.

FIGS. 14 and 15 are cross-sectional views for illustrating step S200 of FIG. 10.

FIGS. 16 to 18 are cross-sectional views for illustrating step S300 of FIG. 10.

FIGS. 19 to 21 are cross-sectional views for illustrating step S400 of FIG. 10.

FIG. 22 is a block diagram of an electronic device according to an embodiment of the present disclosure.

FIG. 23 is a view illustrating electronic devices according to a variety of embodiments of the present disclosure.

### DETAILED DESCRIPTION

Embodiments of the disclosure now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the present disclosure will be described in detail with reference to the accompanying drawings.

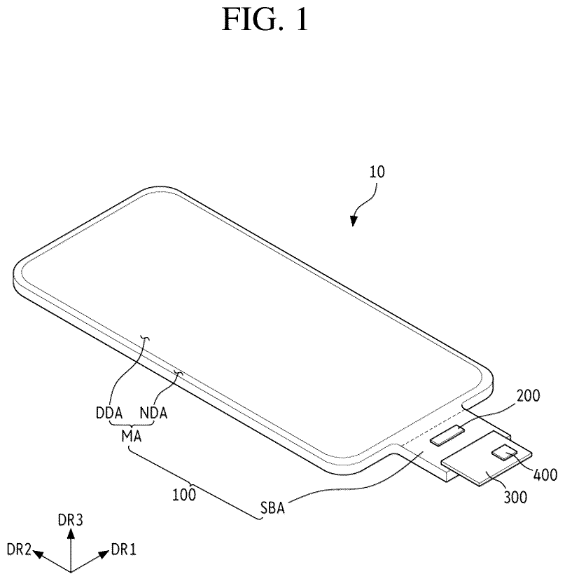

FIG. 1 is a perspective view illustrating a display device according to an embodiment of the present disclosure.

Referring to FIG. 1, a display device 10 may be employed by portable electronic devices such as, for example, a mobile phone, a smart phone, a tablet PC, a mobile communications terminal, an electronic notebook, an electronic book, a portable multimedia player (PMP), a navigation device and a ultra mobile PC (UMPC). For example, the display device 10 may be used as a display unit of a television, a laptop computer, a monitor, an electronic billboard, or the Internet of Things (IOT). In another example, the display device 10 may be applied to wearable devices such as, for example, a smart watch, a watch phone, a glasses-type display, and a head-mounted display (HMD) device.

The display device 10 may have a shape similarly to a quadrangular shape when viewed from the top. For example, the display device 10 may have a shape similar to a rectangle having shorter sides in a first direction DR1 and longer sides in a second direction DR2. The corners where the shorter sides in the first direction DR1 meet the longer sides in the second direction DR2 may be rounded with a predetermined curvature or may be a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA. The main area MA may include the display area DDA including pixels for displaying images, and the non-display area NDA located around the display area DDA.

The display area DDA may output light from a plurality of emission areas or a plurality of openings to be described later. For example, the display panel 100 may include pixel circuits including switching elements, an element insulating layer that defines the emission areas or the openings, and self-light-emitting elements. For example, a self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED). In the following drawings, it is illustrated that the self-luminous element is an organic light-emitting diode.

The non-display area NDA may be disposed on the outer side of the display area DDA. The non-display area NDA may be defined as the edge area of the main area MA of the display panel 100.

The subsidiary area SBA may be extended from one side of the main area MA. The subsidiary area SUB may include a flexible material that can be bent, folded, or rolled. In an example in which the subsidiary area SBA is bent, the subsidiary area SBA may overlap the main area MA in the thickness direction (e.g., third direction DR3). The subsidiary area SBA may include pads connected to the display driver 200 and the circuit board 300. According to another embodiment, the subsidiary area SBA may be eliminated, and the display driver 200 and the pads may be disposed in the non-display area NDA.

The display driver 200 may output signals and voltages for driving the display panel 100. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction as the subsidiary area SBA is bent. In another example, the display driver 200 may be mounted on the circuit board 300.

The circuit board 300 may be attached on the pad area of the display panel 100 using an anisotropic conductive film (ACF). The circuit board 300 may be a flexible printed circuit board (FPCB), a printed circuit board (PCB), or a flexible film such as, for example, a chip-on-film (COF).

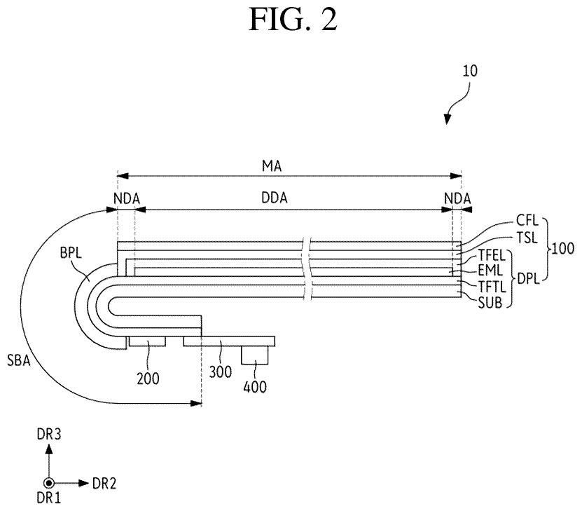

The touch driver 400 may be mounted on the circuit board 300. The touch driver 400 may be connected to a touch sensor layer TSL (see FIG. 2) for touch sensing and driving.

FIG. 2 is a cross-sectional view illustrating a display device according to an embodiment of the present disclosure.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin-film encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as, for example, polyimide PI. According to another embodiment, the substrate SUB may include a glass material or a metal material.

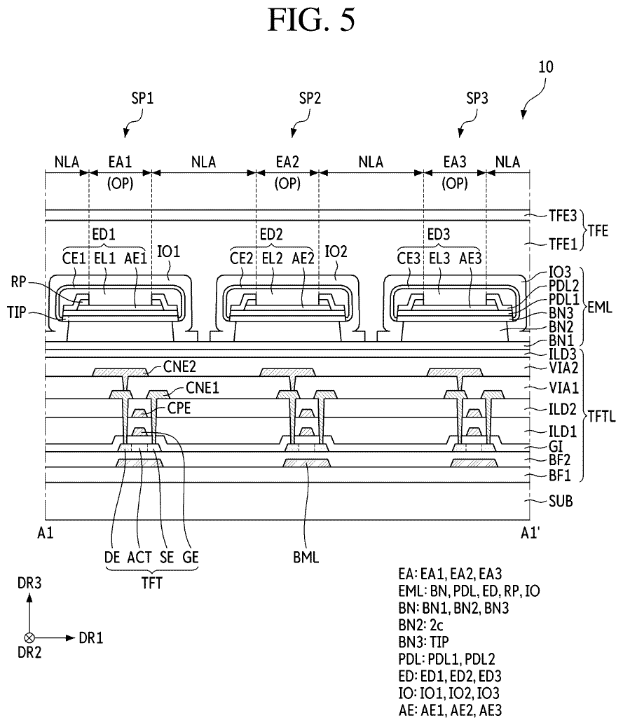

The transistor layer TFTL may be disposed on the substrate SUB. The transistor layer TFTL may be located in the display area DDA, the non-display area NDA and the subsidiary area SBA. The transistor layer TFTL may include a plurality of transistors TFT (see FIG. 5).

The display element layer EML may be disposed on the transistor layer TFTL. The display element layer EML may be located in the display area DDA. The display element layer EML may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The thin-film encapsulation layer TFEL may be located on the display element layer EML. The thin-film encapsulation layer TFEL may be located in the display area DDA and the non-display area NDA. The thin-film encapsulation layer TFEL may cover the upper and side surfaces of the display element layer EML, and can protect the display element layer EML from outside oxygen and moisture. The thin-film encapsulation layer TFEL may include at least one inorganic film and at least one organic film for encapsulating the display element layer EML. The thin-film encapsulation layer TFEL may be eliminated in some implementations.

The touch sensor layer TSL may be disposed on the thin-film encapsulation layer TFEL. The touch sensor layer TSL may be located across the display area DDA and the non-display area NDA. The touch sensor layer TSL may sense a user's touch by mutual capacitance sensing or self-capacitance sensing. The touch sensor layer TSL may be eliminated in some implementations.

The color filter layer CFL may be disposed on the touch sensor layer TSL. The color filter layer CFL may be located in the display area DDA and the non-display area NDA. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensor layer TSL, the display device 10 may be implemented without a separate substrate for the color filter layer CFL. Therefore, the thickness of the display device 10 can be relatively small. The color filter layer CFL may be eliminated in some implementations.

As illustrated in FIG. 2, a portion of the display panel 100 overlapping with the subsidiary area SBA may be bent. In an example in which a portion of the display panel 100 is bent, the display driver 200, the circuit board 300 and the touch driver 400 may overlap with the main area MA in the third direction DR3.

When a part of the display panel 100 is bent, the bending protection layer BPL can protect the underlying structures located in the subsidiary area SBA from bending stress.

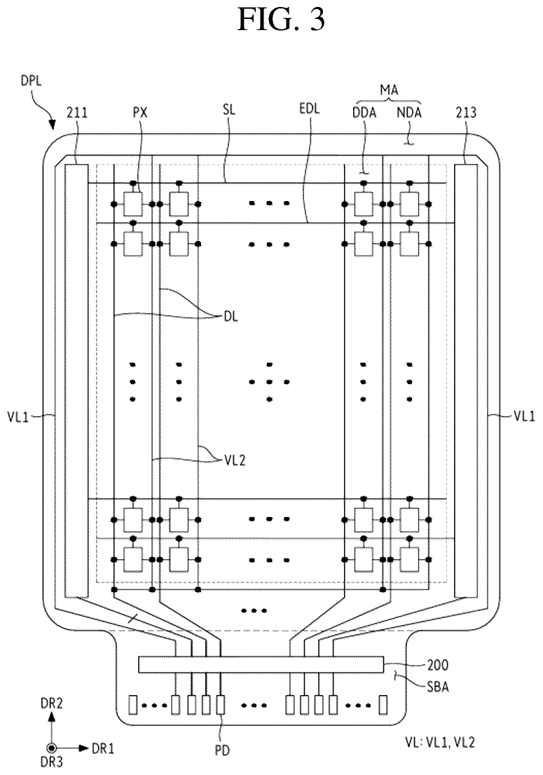

FIG. 3 is a plan view illustrating a display layer of a display device according to an embodiment of the present disclosure.

Referring to FIG. 3, the display layer DPL may include a plurality of pixels PX located in the display area DDA, and a plurality of voltage lines VL, a plurality of scan lines SL, a plurality of emission control lines EDL and a plurality of data lines DL connected to the plurality of pixels PX.

The plurality of scan lines SL may be extended in the first direction DR1 and may be spaced apart from one another in the second direction DR2 intersecting the first direction DR1. The scan lines may be arranged along the second direction DR2. The scan lines SL may sequentially supply a scan signal to the pixels PX.

The emission control lines EDL may be extended in the first direction DR1 and may be spaced apart from one another in the second direction DR2. The emission control lines EDL may be arranged along the second direction DR2. The emission control lines EDL may sequentially supply an emission control signal to the pixels PX.

The data lines DL may be extended in the second direction DR2 and may be spaced apart from one another in the first direction DR1. The data lines DL may be arranged along the first direction DR1. The data lines DL may apply data voltage to the pixels PX. The data voltage may determine the luminance of each of the plurality of pixels PX.

The voltage lines VL may include a main voltage line VL1 and a subsidiary voltage line VL2. At least one of the first supply voltage (high-level voltage) or the second supply voltage (low-level voltage) may be transmitted to the subsidiary voltage line VL2 through the main voltage line VL1 located in the non-display area NDA. In the following description, the main voltage line VL1 and the subsidiary voltage line VL2 may be collectively referred to as voltage lines VL.

The non-display area NDA may surround the display area DDA. The non-display area NDA may include a scan driver 211, an emission control driver 213.

The scan driver 211 may be disposed on an outer side of the display area DDA or on a side of the non-display area NDA. The scan driver 211 may include a plurality of driving transistors for generating gate signals based on a gate control signal.

The emission control driver 213 may be disposed on the opposite outer side of the display area DDA or on the opposite side of the non-display area NDA. The emission control driver 213 may include a plurality of emission control transistors for generating emission signals based on the emission control signal.

The display layer DPL according to the embodiment may include the display driver 200 and a plurality of pad electrodes PD located in the subsidiary area SBA. The plurality of pad electrodes PD may be spaced apart from one another in the first direction DR1, and the pad electrodes PD may be connected to different lines, respectively.

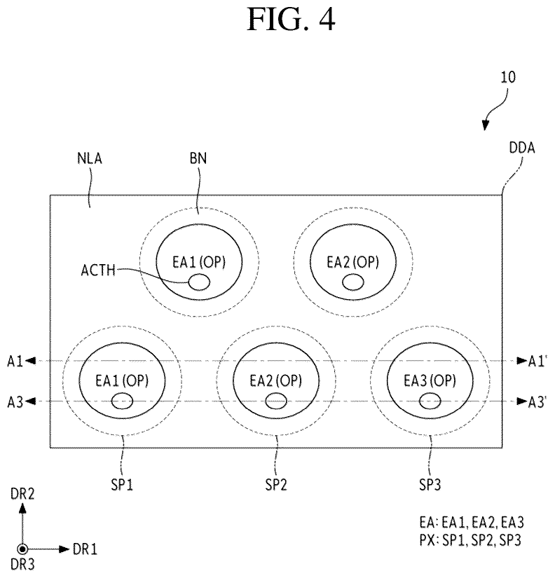

FIG. 4 is a plan view illustrating a plurality of pixels arranged in the display area of FIG. 3.

Referring to FIG. 4, a pixel PX according to embodiments of the present disclosure may include a first sub-pixel SP1, a second sub-pixel SP2 and a third sub-pixel SP3 located in the display area DDA. The first sub-pixel SP1, the second sub-pixel SP2 and the third sub-pixel SP3 may be spaced apart from one another.

The display device 10 according to embodiments of the present disclosure may include emission areas EA and a non-emission area NLA located in the display area DDA. In the emission areas EA, light may be output. In the non-emission area NLA, no light may be output.

The emission areas EA may include a first emission area EA1 that is the emission area of the first sub-pixel SP1, a second emission area EA2 that is the emission area of the second sub-pixel SP2, and a third emission area EA3 that is the emission area of the third sub-pixel SP3. According to embodiments of the present disclosure, the first emission area EA1, the second emission area EA2 and the third emission area EA3 may output lights of different colors. For example, the first emission area EA1 may output red light, the second emission area EA2 may output green light, and the third emission area EA3 may output blue light. It should be understood, however, that the embodiments of the present disclosure are not limited thereto. In some implementations, the first emission area EA1, the second emission area EA2 and the third emission area EA3 may output light of the same color.

When viewed from the top, the emission areas EA according to embodiments of the present disclosure may be defined by openings OP defined by a bank structure BN. In other words, when viewed from the top, the bank structure BN may surround the openings OP.

When viewed from the top, anode contact holes ACTH according to embodiments of the present disclosure may be located in the emission areas EA. The anode contact holes ACTH may be located at different positions within the emission areas EA. The anode contact holes ACTH will be described later.

The non-emission area NLA may refer to the rest of the display area DDA except for the emission areas EA. The non-emission area NLA may surround the first emission area EA1, the second emission area EA2, and the third emission area EA3. The non-emission area NLA can prevent lights the first emission area EA1, the second emission area EA2 and the third emission area EA3 from mixing. The bank structure BN may be disposed in the non-emission area NLA.

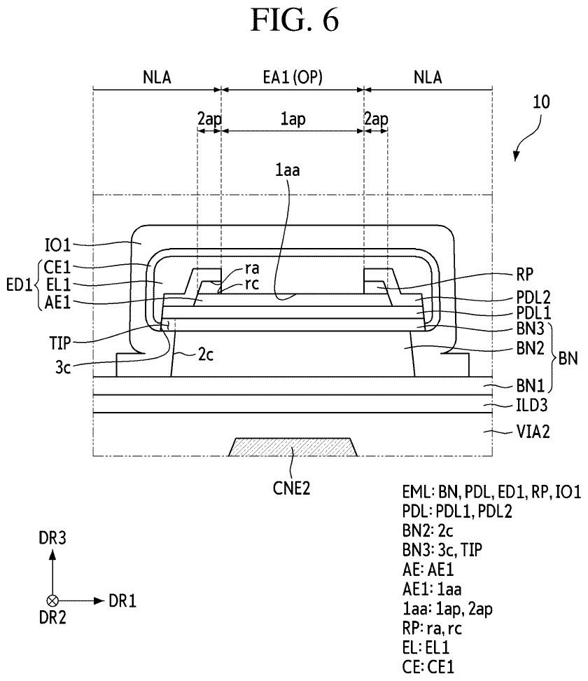

FIG. 5 is a cross-sectional view illustrating an example of the display layer, taken along line A1-A1′ of FIG. 4. FIG. 6 is an enlarged, cross-sectional view of the display element layer in the first emission area in FIG. 5. FIGS. 5 and 6 show the cross-sectional structure of the first sub-pixel SP1, the second sub-pixel SP2 and the third sub-pixel SP3 located in the display area DDA of the display device 10.

Referring to FIGS. 5 and 6, the transistor layer TFTL may be disposed on the substrate SUB. The transistor layer TFTL may include a first buffer layer BF1, a bottom metal layer BML), a second buffer layer BF2, a transistor TFT, a gate insulator GI, a first insulating layer ILD1, a capacitor electrode CPE, a second insulating layer ILD2, a first connection electrode CNE1, a first via layer VIA1, a second connection electrode CNE2, a second via layer VIA2, and a third insulating layer ILD3.

The first buffer layer BF1 may be disposed on the substrate SUB. The first buffer layer BF1 may include an inorganic film capable of preventing permeation of air or moisture. For example, the first buffer layer BF1 may include a plurality of inorganic films stacked on one another alternately.

The bottom metal layer BML may be disposed on the first buffer layer BF1. The bottom metal layer BML may include a conductive metal and, for example, may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films stacked on one another alternately.

The transistor TFT may be disposed on the second buffer layer BF2 and may form a pixel circuit. For example, the transistor TFT may be a driving transistor or a switching transistor of the pixel circuit.

The transistor TFT may include an active layer ACT, a source electrode SE, a drain electrode DE and a gate electrode GE.

The active layer ACT may be disposed on the second buffer layer BF2. The active layer ACT may overlap with the gate electrode GE in the third direction DR3 and may be insulated from the gate electrode GE by the gate insulator GI. The source electrode SE and the drain electrode DE may be formed as parts of the active layer ACT become conductive.

The gate insulator GI may be disposed over the active layer ACT. The gate insulator GI may cover the active layer ACT and the second buffer layer BF2, and the gate insulator GI may insulate the active layer ACT from the gate electrode GE. The gate insulator GI may include a contact hole through which the first connection electrode CNE1 passes.

The gate electrode GE may be disposed on the gate insulator GI. The gate electrode GE may overlap the active layer ACT, with the gate insulator GI interposed between the gate electrode GE and the active layer ACT.

The gate electrode GE may include a conductive metal and, for example, may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric layer ILD1 may cover the gate electrode GE and the gate insulator GI. The first interlayer dielectric film ILD1 may include a contact hole through which the first connection electrode CNE1 passes. The contact hole of the first interlayer dielectric layer ILD1 may be connected to the contact hole of the gate insulator GI and the contact hole of the second interlayer dielectric layer ILD2.

The capacitor electrode CPE may be disposed on the first insulating layer ILD1. The capacitor electrode CPE may overlap with the gate electrode GE in the third direction DR3. The capacitor electrode CPE and the gate electrode GE may form a capacitance.

The second insulating layer ILD2 may cover the capacitor electrode CPE and the first insulating layer ILD1. The second insulating layer ILD2 may include the contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be disposed on the second interlayer dielectric layer ILD2. The first connection electrode CNE1 may electrically connect the drain electrode DE of the transistor TFT with the second connection electrode CNE2. The first connection electrode CNE1 may be inserted into the contact holes formed in the first interlayer dielectric layer ILD1, the second interlayer dielectric layer ILD2 and the gate insulator GI to be in contact with the drain electrode DE of the transistor TFT.

The first via layer VIA1 may be disposed on the first connection electrode CNE1 and the second interlayer dielectric layer ILD2. The first via layer VIA1 may provide a flat surface over the underlying structures. The first via layer VIA1 may include a contact hole through which the second connection electrode CNE2 passes.

The first via layer VIA1 may include an organic insulating material. For example, the first via layer VIA1 may include an acrylic resin, polyimide, polyamide, benzocyclobutene, a phenol resin, or the like.

The second connection electrode CNE2 may be disposed on the first via layer VIA1. The second connection electrode CNE2 may be inserted into a contact hole formed in the first via layer VIA1 to be in contact with the first connection electrode CNE1.

The second via layer VIA2 may be disposed on the second connection electrode CNE2 and the first via layer VIA1.

The second via layer VIA2 may include an organic material. For example, the second via layer VIA2 may include an acrylic resin, polyimide, polyamide, benzocyclobutene, a phenol resin, or the like.

The third interlayer dielectric layer ILD3 may be disposed on the second via layer VIA2. The third insulating layer ILD3 can help prevent outgassing caused by the organic material of the second via layer VIA2 from permeating into the display element layer EML.

The third interlayer dielectric layer ILD3 may include an inorganic insulating material. For example, the third insulating layer ILD3 may include at least one of silicon nitride, silicon oxide and silicon oxynitride.

The display element layer EML may be disposed on the transistor layer TFTL. The display element layer EML may include a bank structure BN, an element insulating layer PDL, a light-emitting element ED, a residual pattern RP, and an inorganic element layer IO.

According to embodiments of the present disclosure, the bank structure BN may be disposed on the second via layer VIA2. The bank structure BN may be located in line with the emission areas EA. There may be a plurality of bank structures BN. The plurality of bank structures BN may be spaced apart from one another at the non-emission area NLA. In other words, the bank structures BN may be formed in a pattern of islands.

The bank structure BN may include a first bank layer BN1, a second bank layer BN2, and a third bank layer BN3. The first bank layer BN1, the second bank layer BN2 and the third bank layer BN3 may be stacked on in this order in the third direction DR3.

The first bank layer BN1 may be disposed on the third insulating layer ILD3. The first bank layer BN1 may entirely cover the third insulating layer ILD3 in the emission areas EA and the non-emission area NLA.

The first bank layer BN1 may assist in applying a low-level voltage to the cathode electrode CE.

The first bank layer BN1 may include a conductive metal having etching resistance. For example, the first bank layer BN1 may be formed of titanium (Ti).

The second bank layer BN2 may be in contact with the first bank layer BN1. The second bank layers BN2 may be electrically connected to the first bank layers BN1. The second bank layer BN2 may assist in electrically connecting the first bank layer BN1 with the cathode electrode CE.

The second bank layer BN2 may include a metal having high electrical conductivity. For example, the second bank layer BN2 may include aluminum (Al).

According to embodiments of the present disclosure, the second bank layer BN2 located in the first emission area EA1, the second bank layer BN2 located in the second emission area EA2, and the second bank layer BN2 located in the third emission area EA3 may be electrically connected by the first bank layer BN1.

The third bank layer BN3 may be disposed on the second bank layer BN2. The third bank layer BN3 may include a conductive metal having etching resistance. For example, the third bank layer BN3 may be formed of titanium (Ti).

According to embodiments of the present disclosure, the third bank layer BN3 located in the first emission area EA1, the third bank layer BN3 located in the second emission area EA2, and the third bank layer BN3 located in the third emission area EA3 may be electrically connected by the second bank layer BN2 and the first bank layer BN1.

According to embodiments of the present disclosure, the second bank layer BN2 may include a side surface 2c facing the non-emission area NLA, and the third bank layer BN3 may include a side surface 3c facing the non-emission area NLA.

The side surface 3c of the third bank layer BN3 may protrude toward the non-emission area NLA more than the side surface 2c of the second bank layer BN2. In other words, the third bank layer BN3 may include tip that protrude on the both sides toward the non-emission area NLA more than the side surfaces 2c of the second bank layer BN2, respectively. Accordingly, the side surfaces 2c of the second bank layer BN2 and the tips TIP of the third bank layer BN3 may form undercuts, and the bank structure BN may have an overhang structure.

In the display device 10 according to embodiments of the present disclosure, the bank structure BN includes the tips TIP, a first light-emitting element ED1, a second light-emitting element ED2 and a third light-emitting element ED3 may be spaced apart from each other without any fine metal mask during the fabrication process. Such a fabrication process will be described later.

According to embodiments of the present disclosure, the height of the second bank layer BN2 may be higher than the height of the first bank layer BN1 and the height of the third bank layer BN3, but embodiments of the present disclosure are not limited thereto.

The first element insulating layer PDL1 may be disposed on the third bank layer BN3. The first element insulating layer PDL1 may entirely cover the upper surface of the third bank layer BN3. The first element insulating layer PDL1 may overlap with the tip TIP of the third bank layer BN3 in the third direction DR3.

The first element insulating layer PDL1 may insulate the bank structure BN from the anode electrode AE. Accordingly, the first element insulating layer PDL1 can solve defects caused by contact between the bank structure BN and the anode electrode AE, and thus can prevent a short-circuit defect of the display device 10.

The first element insulating layer PDL1 may include an inorganic insulating material. For example, the first element insulating layer PDL1 may include at least one of silicon nitride, silicon oxide and silicon oxynitride.

The second element insulating layer PDL2 may be disposed on the first element insulating layer PDL1. The second element insulating layer PDL2 may define an opening OP and may expose the anode electrode AE in the opening OP. In other words, the second element insulating layer PDL2 may surround the opening OP and cover the edge of the anode electrode AE. The second element insulating layer PDL2 may overlap with the tip TIP of the third bank layer BN3 in the third direction DR3.

The second element insulating layer PDL2 may include an inorganic insulating material. For example, the second element insulating layer PDL2 may include at least one of silicon nitride, silicon oxide and silicon oxynitride.

According to embodiments of the present disclosure, light-emitting elements ED may be disposed on the bank structure BN and the element insulating layer PDL. According to embodiments of the present disclosure, the light-emitting elements ED may be disposed on the bank structure BN and the element insulating layer PDL.

For a case in which the display device 10 according to embodiments of the present disclosure is applied to a high-resolution electronic device 1, the display device 10 may include a plurality of light-emitting elements ED which are included in the display element layer EML and arranged with an appropriate distance within a narrow area to implement the high-resolution. Accordingly, in the display device 10 according to embodiments of the present disclosure, a plurality of light-emitting elements ED is formed on the bank structure BN, such that the light-emitting elements ED can be arranged with an appropriate distance within a narrow area. The electronic device 1 will be described later.

The light-emitting elements ED may include a first light-emitting element ED1 disposed in the first emission area EA1, a second light-emitting element ED2 disposed in the second emission area EA2, and a third light-emitting element ED3 disposed in the third emission area EA3. The first light-emitting element ED1, the second light-emitting element ED2 and the third light-emitting element ED3 may be spaced apart from one another.

The first light-emitting element ED1 may include a first anode electrode AE1, a first emissive layer EL1 and a first cathode electrode CE1, the second light-emitting element ED2 may include a second anode electrode AE2, a second emissive layer EL2 and a second cathode electrode CE2, and the third light-emitting element ED3 may include a third anode electrode AE3, a third emissive layer EL3 and a third cathode electrode CE3.

The first light-emitting element ED1, the second light-emitting element ED2 and the third light-emitting element ED3 may output lights of different colors. For example, the first light-emitting element ED1 may emit red light, the second light-emitting element ED2 may emit green light, and the third light-emitting element ED3 may emit blue light.

The anode electrode AE may be disposed on the first element insulating layer PDL1. The anode electrode AE may be in contact with the first element insulating layer PDL1. As described herein, the anode electrode AE may be separated from the bank structure BN by the first element insulating layer PDL1.

The anode electrodes AE may include a first anode electrode AE1, a second anode electrode AE2, and a third anode electrode AE3. The first anode electrode AE1 may be located in the first emission area EA1, the second anode electrode AE2 may be located in the second emission area EA2, and the third anode electrode AE3 may be located in the third emission area EA3. The first anode electrode AE1, the second anode electrode AE2, and the third anode electrode AE3 may be spaced apart from one another.

The anode electrodes AE may have a stack structure of a material layer having a high work function such as, for example, indium-tin-oxide (ITO), indium-zinc-oxide (IZO), zinc oxide (ZnO) and indium oxide (In₂O₃), and a reflective material layer such as, for example, silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anode electrodes AE may have, but is not limited to, a multilayer structure of ITO/Mg, ITO/MgF, ITO/Ag, and ITO/Ag/ITO.

According to embodiments of the present disclosure, an undercut may be formed between the anode electrode AE and the second element insulating layer PDL2 in the non-emission area NLA. In other words, the upper surface of the anode electrode AE and the second element insulating layer PDL2 may be spaced apart from each other in the third direction DR3 in the non-emission area NLA.

A residual pattern RP may be located between the anode electrode AE and the second element insulating layer PDL2 in the non-emission area NLA. In other words, the residual pattern RP may be located at the undercut formed between the anode electrode AE and the second element insulating layer PDL2.

The residual pattern RP may be located between the anode electrode AE and the second element insulating layer PDL2 in the third direction DR3 in contact with them. The residual pattern RP may surround the opening OP.

The residual pattern RP may be formed in the process of fabricating the display device 10 to prevent damage to the anode electrode AE in a dry etching process. The residual pattern RP may be formed entirely on the anode electrode AE in the process of fabricating the display device 10 and may remain in the form as illustrated in the drawings. Such a fabrication process will be described later.

The residual pattern RP may include a transparent conductive material (TCO). For example, the residual pattern RP may include at least one of indium-zinc-oxide (IZO) and indium-tin-oxide (ITO).

The residual pattern RP included in the display device 10 may be formed to overlap with the bank structure BN, the element insulating layer PDL, the light-emitting element ED, and the element inorganic layer IO in the third direction DR3.

According to embodiments of the present disclosure, the residual pattern RP may include a first surface ra and a side surface rc (later identified at FIG. 6). The first surface ra of the residual pattern RP may face the second element insulating layer PDL2 in the third direction (DR3), and the side surface rc of the residual pattern RP may face the emission area EA or the opening OP.

The second element insulating layer PDL2 may be in contact with and cover the first surface ra of the residual pattern RP. Although the first surface ra of the residual pattern RP is entirely covered by the second element insulating layer PDL2 in the drawings, embodiments of the present disclosure are not limited thereto. In some implementations, a part of the first surface ra of the residual pattern RP may not be covered by the second element insulating layer PDL2 and may be exposed.

The side surface rc of the residual pattern RP may not be in contact with the second element insulating layer PDL2. In other words, the side surface rc of the residual pattern RP may not be covered by the element insulating layer PDL and may be exposed. The side surface rc of the residual pattern RP may be in contact with an emissive layer EL described herein.

As the display device 10 according to embodiments of the present disclosure includes the residual pattern RP, incorporation of the residual pattern RP may address reliability problems that may occur through an empty space or a void formed at an edge of an anode electrode AE during the fabrication process. Such a fabrication process will be described later.

The emissive layer EL may be disposed on the anode electrode AE. The emissive layer EL may be located in the emission areas EA and the non-emission area NLA. The emissive layer EL may be in contact with the anode electrode AE in the opening OP and may entirely cover the second element insulating layer PDL2 in the non-emission area NLA. The emissive layer EL may overlap with the bank structure BN in the third direction DR3.

The emissive layers EL may include a first emissive layer EL1, a second emissive layer EL2, and a third emissive layer EL3. The first emissive layer EL1 may be located in the first emission area EA1, the second emissive layer EL2 may be located in the second emission area EA2, and the third emissive layer EL3 may be located in the third emission area EA3. The first emissive layer EL1, the second emissive layer EL2 and the third emissive layer EL3 may be spaced apart from one another in the non-emission area NLA.

The emissive layer EL may be an organic emissive layer formed of an organic material. The emissive layer EL may include all of the materials typically used. The first emissive layer EL1, the second emissive layer EL2 and the third emissive layer EL3 may emit lights of different colors. For example, the first emissive layer EL1 may emit red light, the second emissive layer EL2 may emit green light, and the third emissive layer EL3 may emit blue light, but embodiments of the present disclosure are not limited thereto.

In the display device 10 according to embodiments of the present disclosure, as the third bank layer BN3 of the bank structure BN includes the tips, the first to third emissive layers EL1, EL2 and EL3 can be formed without a fine metal mask during the process of fabricating the display device 10.

As illustrated in FIG. 6, the first anode electrode AE1 may include an upper surface 1aa. The upper surface 1aa of the first anode electrode AE1 may face one side in the third direction DR3.

According to embodiments of the present disclosure, the upper surface 1aa of the first anode electrode AE1 may be in contact with the first emissive layer EL1 in the emission area EA or the opening OP, and the upper surface 1aa of the first anode electrode AE1 may be in contact with the residual pattern EP in the non-emission area NLA. In other words, in the non-emission area NLA, the upper surface 1aa of the first anode electrode AE1 may be spaced apart from the second element insulating layer PDL2 in the third direction DR3.

In other words, the upper surface 1aa of the first anode electrode AE1 may be divided into a first portion 1ap and a second portion 2ap, which come in contact with different layers, respectively. The first portion 1ap may be in contact with the first emissive layer EL1, and the second portion 2ap may be in contact with the residual pattern RP. The first portion 1ap may be located in the emission area EA, and the second portion 2ap may be located in the non-emission area NLA. In some aspects, the first portion 1ap may be located at the center of the upper surface 1aa, and the second portion 2ap may be located at an edge of the upper surface 1aa.

The cathode electrode CE may be disposed on the emissive layer EL. The cathode electrode CE may be disposed in the emission areas EA and the non-emission area NLA. The cathode electrode CE may entirely cover the emissive layer EL. The cathode electrode CE may be in contact with the bank structure BN, and thus may be electrically connected to the bank structure BN. Specifically, the cathode electrode CE may be in contact with a tip of the third bank layer BN3.

The cathode electrode CE may include a transparent conductive material such that light generated in the emissive layer EL can exit. For example, the cathode electrode CE may include a material layer having a small work function such as, for example, Li, Ca, LiF/Ca, LiF/Al, Al, Mg, Ag, Pt, Pd, Ni, Au, Nd, Ir, Cr, BaF and Ba, or a compound or mixture thereof (e.g., a mixture of Ag and Mg). The cathode electrode CE may further include a transparent metal oxide layer disposed on the material layer having a small work function.

The cathode electrodes CE may include a first cathode electrode CE1, a second cathode electrode CE2, and a third cathode electrode CE3. The first cathode electrode CE1 may be disposed in the first emission area EA1, the second cathode electrode CE2 may be disposed in the second emission area EA2, and the third cathode electrode CE3 may be disposed in the third emission area EA3. The first cathode electrode CE1, the second cathode electrode CE2 and the third cathode electrode CE3 may be spaced apart from one another in the non-emission area NLA.

According to embodiments of the present disclosure, the first cathode electrode CE1, the second cathode electrode CE2 and the third cathode electrode CE3 may not be directly connected with one another but may be electrically connected with one another through the bank structure BN. In other words, the first cathode electrode CE1, the second cathode electrode CE2, and the third cathode electrode CE3 may be in contact with the third bank layer BN3, and the first cathode electrode CE1, the second cathode electrode CE2, and the third cathode electrode CE3 may be electrically connected with each other through the second bank layer BN2 and the first bank layer BN1 that are electrically connected to the third bank layer BN3.

In the display device 10 according to embodiments of the present disclosure, since the third bank layer BN3 of the bank structure BN includes the tips, the first cathode electrode CE1, the second cathode electrode CE2 and the third cathode electrode CE3 can be formed without a separate fine metal mask.

Although not illustrated in the drawings, an auxiliary electrode may be further disposed on the cathode electrode CE. The auxiliary electrode may include a transparent conductive material and may assist in electrically connecting the cathode electrode CE with the bank structure BN.

The element inorganic layer IO may be disposed on the light-emitting element ED. The element inorganic layer IO may completely cover the light-emitting element ED and can prevent oxygen or moisture from permeating into the light-emitting element ED.

The element inorganic layer IO may include an inorganic insulating material. For example, the element inorganic layer IO may include one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be disposed on the first light-emitting element ED1 in the first emission area EA1, the second element inorganic layer IO2 may be disposed on the second light-emitting element ED2 in the second emission area EA2, and the third element inorganic layer IO3 may be disposed on the third light-emitting element ED3 in the third emission area EA3. The first element inorganic layer IO1, the second element inorganic layer IO2 and the third element inorganic layer IO3 may be spaced apart each other in the non-emission area NLA.

Although the first element inorganic layer IO1, the second element inorganic layer IO2 and the third element inorganic layer IO3 appear to be formed on the same layer in the drawings, in the process of fabricating the display device 10, the first element inorganic layer IO1 may be formed after the first light-emitting element ED1 has been formed, the second element inorganic layer IO2 may be formed after the second light-emitting element ED2 has been formed, and the third element inorganic layer IO3 may be formed after the third light-emitting element ED3 has been formed. Such a fabrication process will be described later.

The element inorganic layer IO may be in contact with the side surface 2c of the second bank layer BN2. In some implementations, the element inorganic layer IO may be in contact with a surface of the first bank layer BN1 or may be spaced apart from the surface of the first bank layer BN1 in the third direction DR3.

The thin-film encapsulation layer TFEL may be located on the display element layer EML. The thin-film encapsulation layer TFEL may include an organic encapsulation layer TFE1 and an inorganic encapsulation layer TFE3.

According to the embodiment, the organic encapsulation layer TFE1 may be disposed on the element inorganic layer IO. For example, the organic encapsulation layer TFE1 may cover the first element inorganic layer IO1, the second element inorganic layer IO2, and the third element inorganic layer IO3 in contact with them generally.

The organic encapsulation layer TFE1 may provide a flat surface over the height difference created by the profile of the underlying structures.

The organic encapsulation layer TFE1 may include a polymer-based material. For example, the organic encapsulation layer TFE1 may include an acrylic resin, a silicone resin, an epoxy resin, a silicone acrylic resin, polyimide, polyethylene, or the like.

The inorganic encapsulating layer TFE3 may be located on the organic encapsulating layer TFE1. The inorganic encapsulation layer TFE3 can protect the underlying structures from permeation of moisture and oxygen. The inorganic encapsulation layer TFE3 may be eliminated in some implementations.

The inorganic encapsulation layer TFE3 may include an inorganic insulating material. For example, the inorganic encapsulation layer TFE3 may include one of silicon nitride, silicon oxide, and silicon oxynitride.

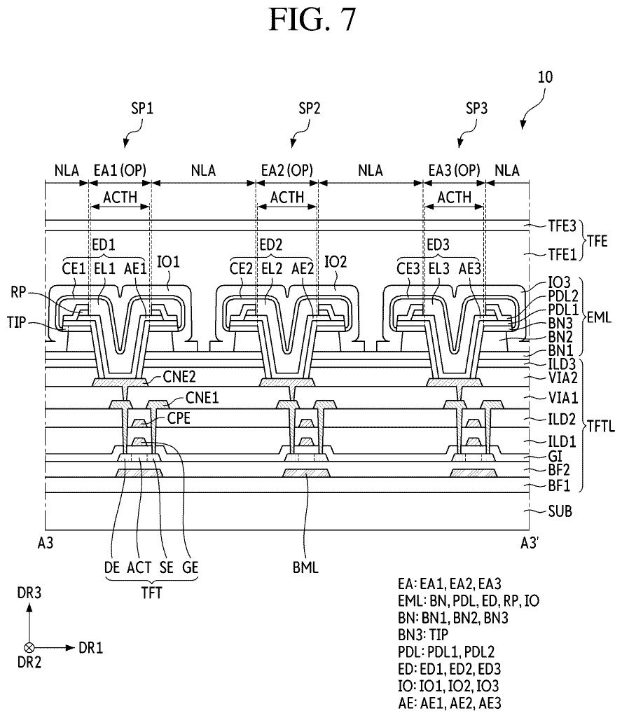

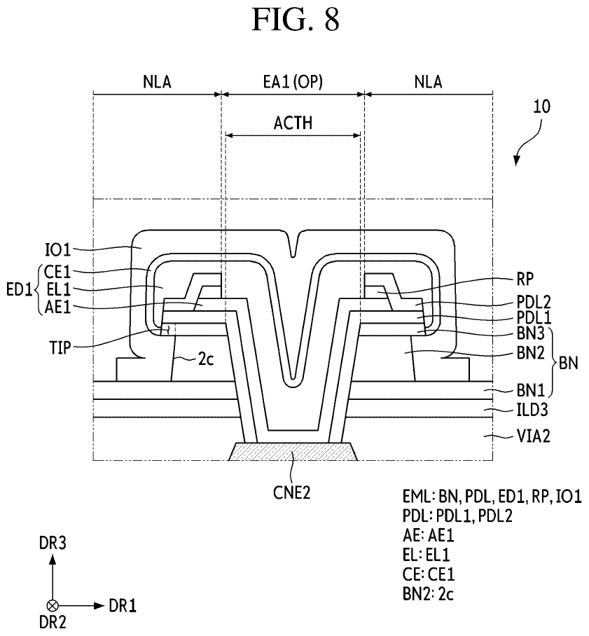

FIG. 7 is a cross-sectional view illustrating an example of the display layer, taken along line A3-A3′ of FIG. 7. FIG. 8 is an enlarged, cross-sectional view of the display element layer in the first emission area in FIG. 7.

In the following descriptions, FIGS. 7 and 8 show the cross-sectional structure of the first sub-pixel SP1, the second sub-pixel SP2 and the third sub-pixel SP3 in line with anode contact holes ACTH in the display area DDA of the display device 10. In the following descriptions, redundant descriptions of like elements will be omitted. The structure of the display element layer EML in line with the anode contact hole ACTH will be described.

Referring to FIGS. 7 and 8 in conjunction with FIGS. 5 and 6, the second connection electrode CNE2 may be located in the emission area EA. The anode electrode AE may be in contact with the second connection electrode CNE2 through the anode contact hole ACTH. Accordingly, the anode electrode AE may be electrically connected to the second connection electrode CNE2.

According to embodiments of the present disclosure, the anode contact hole ACTH may be located such that the anode contact hole ACTH overlaps with the emission area EA. The anode contact hole ACTH may penetrate the second via layer VIA2, the third insulating layer ILD3, the first bank layer BN1, the second bank layer BN2 and the third bank layer BN3. In other words, the second via layer VIA2, the third insulating layer ILD3 and the bank structure BN may surround the anode contact hole ACTH.

In the process of fabricating the display device 10, the process of forming the anode contact hole ACTH may include simultaneously removing parts of the second via layer VIA2, the third insulating layer ILD3, the first bank layer BN1, the second bank layer BN2, and the third bank layer BN3. Accordingly, the side surface of the second via layer VIA2, the side surface of the third insulating layer ILD3, the side surface of the first bank layer BN1, the side surface of the second bank layer BN2 and the side surface of the third bank layer BN3 facing the anode contact hole ACTH may be located on the same line.

As described herein, the third bank layer BN3 may include a tip that protrudes in the first direction DR1 more than the side surface 2c of the second bank layer BN2. The tip of the third bank layer BN3 may be located on the opposite side where the anode contact hole ACTH is located.

According to embodiments of the present disclosure, the first element insulating layer PDL1 may have a height difference at the anode contact hole ACTH. The first element insulating layer PDL1 may be in contact with and cover the side surface of the second via layer VIA2, the side surface of the third insulating layer ILD3, the side surface of the first bank layer BN1, the side surface of the second bank layer BN2, and the side surface of the third bank layer BN3. The first element insulating layer PDL1 may completely cover the side surface of the second via layer VIA2, the side surface of the third insulating layer ILD3, the side surface of the first bank layer BN1, the side surface of the second bank layer BN2 and the side surface of the third bank layer BN3. Accordingly, the first element insulating layer PDL1 can prevent contact between the anode electrode AE and the bank structure BN, and can address a short-circuit defect caused by the contact between the anode electrode AE and the bank structure BN.

According to the embodiment, the residual pattern RP and the second element insulating layer PDL2 may surround the anode contact hole ACTH. The residual pattern RP and the second element insulating layer PDL2 may not overlap with the anode contact hole ACTH. Other redundant descriptions will be omitted.

According to the embodiment, the emissive layer EL may include a height difference formed by the shape of the anode electrode AE in the anode contact hole ACTH. The emissive layer EL may be in contact with the anode electrode AE and cover the anode electrode AE in the anode contact hole ACTH. Other redundant descriptions will be omitted.

According to the embodiment, the cathode electrode CE may include a height difference formed by the shape of the emissive layer EL in the anode contact hole ACTH. The cathode electrode CE may be in contact with and cover the emissive layer EL in the anode contact hole ACTH. Other redundant descriptions will be omitted.

According to the embodiment, the element inorganic layer IO may include a height difference formed by the shape of the emissive layer EL in the anode contact hole ACTH. The element inorganic layer IO may be in contact with and cover the emissive layer EL in the anode contact hole ACTH. Other redundant descriptions will be omitted.

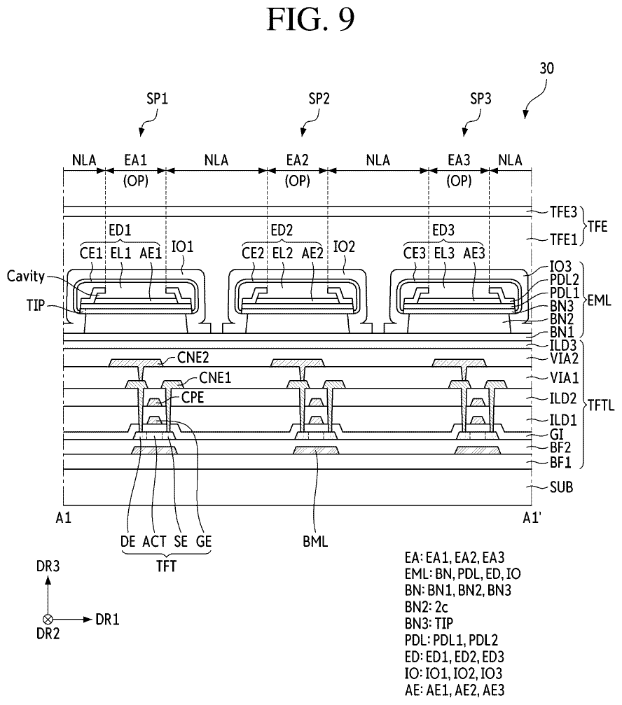

FIG. 9 is a cross-sectional view illustrating another example of the display layer, taken along line A1-A1′ of FIG. 4.

A display element layer EML included in a display device 30 illustrated in FIG. 9 may be different from the display element layer EML included in the display device 10 in including a light-emitting element ED, an element insulating layer PDL, a bank structure BN, and an element inorganic layer IO.

The display element layer EML included in the display device 30 may include the light-emitting element ED, the element insulating layer PDL, the bank structure BN, and the element inorganic layer IO. The light-emitting element ED, the element insulating layer PDL, the bank structure BN and the element inorganic layer IO included in the display device 30 may have the same structures and features as the light-emitting element ED, the element insulating layer PDL, the bank structure BN and the element inorganic layer IO included in the display device 10. Hereinafter, the common structures included in the display device 10 as well as the display device 30 will not be described, and the descriptions will focus on differences.

An undercut may be formed between the anode electrode AE and the second element insulating layer PDL2 in the non-emission area NLA of the display device 30. In other words, the upper surface of the anode electrode AE and the second element insulating layer PDL2 may be spaced apart from each other in the third direction DR3 in the non-emission area NLA. The upper surface of the anode electrode AE included in the display device 30 may be spaced apart from the second element insulating layer PDL2, with a cavity between the upper surface of the anode electrode AE and the second element insulating layer PDL2.

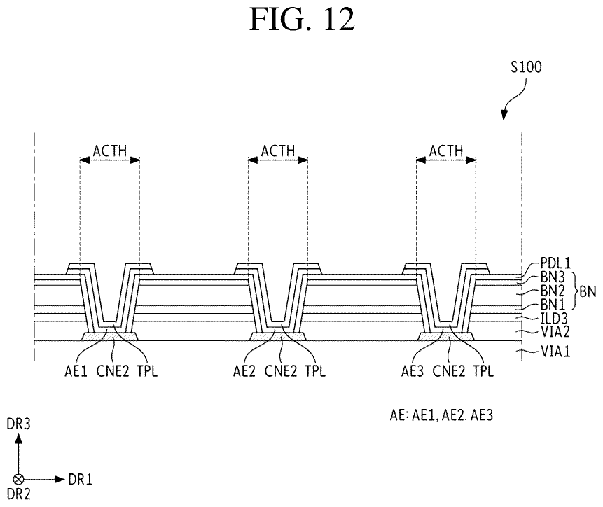

The cavity included in the display device 30 may be formed by forming a temporary layer TPL (see FIG. 12) entirely on the anode electrode AE during the fabrication process, and then removing the temporary layer TPL (see FIG. 12) entirely in a subsequent process. Such a fabrication process will be described later.

A part of the cavity included in the display device 30 may be filled with the emissive layer EL, or an empty space may be formed.

The cavity included in the display device 30 may be formed to overlap with the bank structure BN, the element insulating layer PDL, the light-emitting element ED, and the element inorganic layer IO in the third direction DR3.

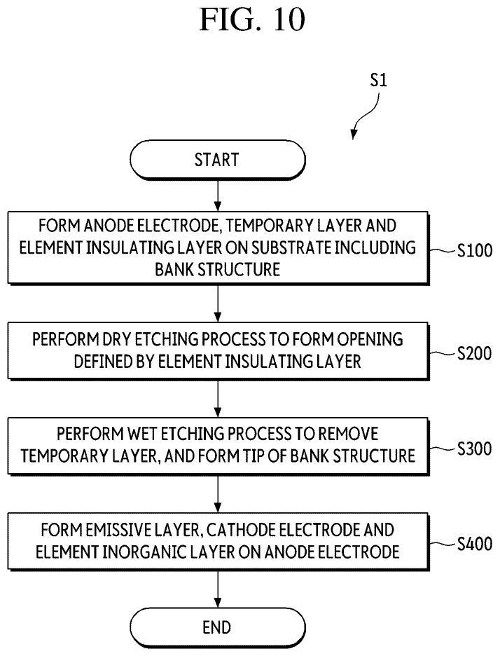

FIG. 10 is a flowchart for illustrating a method for fabricating the display element layer in FIG. 7.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 10, a method for fabricating a display element layer EML included in a display device 10 according to the embodiment (S1) may include: forming an anode electrode, a temporary layer, and an element insulating layer on a substrate including a bank structure (step S100); performing a dry etching process to form an opening defined by the element insulating layer (step S200); performing a wet etching process to remove the temporary layer to form a tip of the bank structure (step S300); and forming an emissive layer, a cathode electrode, and an element inorganic layer on the anode electrode.

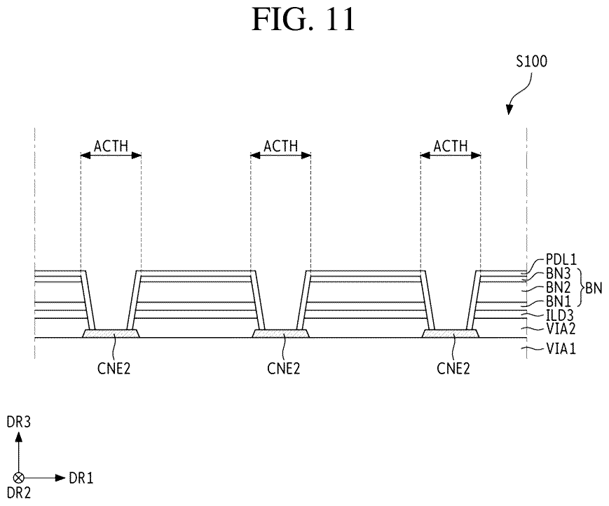

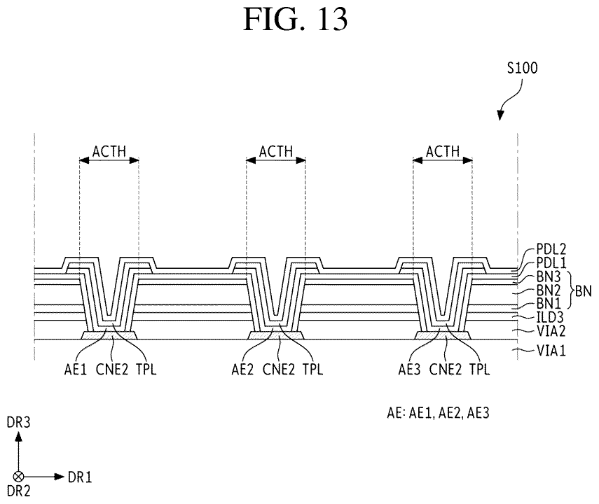

FIGS. 11 to 13 are cross-sectional views for illustrating step S100 of FIG. 10.

Referring to FIGS. 11 to 13, step S100 of forming an anode electrode, a temporary layer, and an element insulating layer on a substrate including a bank structure will be described.

Initially, the method may include forming a plurality of second connection electrodes CNE2 on the first via layer VIA1, and further, forming a second via layer VIA2, a third insulating layer ILD3, and a bank structure BN entirely on the second connection electrode CNE2. The bank structure BN may include a first bank layer BN1, a second bank layer BN2, and a third bank layer BN3 in this order.

In step S100, the second bank layer BN2 and the third bank layer BN3 may include different materials. For example, the third bank layer BN3 may include a material having etching resistance greater than an etching resistance of a material included in the second bank layer BN2. The redundant descriptions will be omitted.

Although not illustrated in the drawings, a thin-film transistor layer TFTL including a first via layer VIA1 and a second via layer VIA2 may be disposed on the substrate SUB. The structure of the thin-film transistor layer TFTL is identical to the structure illustrated in FIG. 5.

Subsequently, the method may include forming an anode contact hole ACTH in line with the second connection electrode CNE2. For example, the process of forming the anode contact hole ACTH may include a photo-patterning process.

In this process, the process of forming the anode contact hole ACTH may include simultaneously penetrating the second via layer VIA2, the third insulating layer ILD3, and the bank structure BN. Accordingly, the side surfaces of the second via layer VIA2, the third insulating layer ILD3, the first bank layer BN1, the second bank layer BN2, and the third bank layer BN3 facing the anode contact hole ACTH may be located on the same line.

In step S100, the second connection electrode CNE2 may be exposed in the anode contact hole ACTH.

Subsequently, the method may include forming a first element insulating layer PDL1 on the bank structure BN and the second connection electrode CNE2.

In step S100, the process of forming the first element insulating layer PDL1 may include a process of forming a film of at least one of the inorganic materials listed herein (e.g., a deposition process), and a process of patterning the inorganic material (e.g., an etching process).

In step S100, the method may include temporarily forming the first element insulating layer PDL1 such that the first element insulating layer PDL1 completely covers the second connection electrode CNE2 and then partially removing the first element insulating layer PDL1 via a subsequent patterning process, such that the second connection electrode CNE2 is exposed.

Subsequently, the method may include forming an anode electrode AE on the second connection electrode CNE2.

In step S100, the method may include forming the temporary layer TPL. The process of forming the temporary layer TPL may include a process of forming a film of at least one of the metal materials listed herein (e.g., sputtering) and a process of patterning the metal material (e.g., an etching process).

In step S100, the anode electrode AE may be entirely in contact with the second connection electrode CNE2 exposed in the anode contact hole ACTH, and the anode electrode AE may extend from the second connection electrode CNE2 such that the anode electrode AE covers the first element insulating layer PDL1.

In step S100, the anode electrode AE may include a first anode electrode AE1, a second anode electrode AE2, and a third anode electrode AE3. The first anode electrode AE1, the second anode electrode AE2, and the third anode electrode AE3 may be spaced apart from one another in the first direction DR1. The redundant descriptions will be omitted.

Subsequently, a temporary layer TPL is formed on the anode electrode AE.

In step S100, the process of forming the temporary layer TPL may include a process of forming a film of at least one of the metal materials listed herein (e.g., sputtering), and a process of patterning the metal material (e.g., an etching process).

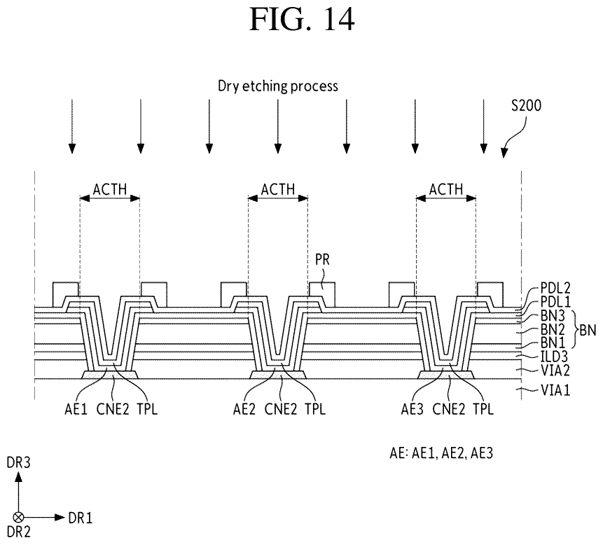

In step S100, the temporary layer TPL may cover the entire upper surface of the anode electrode AE. The temporary layer TPL as formed may prevent damage to the anode electrode AE by a subsequent dry process (the dry etching process of FIG. 14). The temporary layer TPL can assist in preventing the anode electrode AE from being exposed in the dry etching process. That is to say, the temporary layer TPL may work as an etch stopper for the dry etching process.

In step S100, the temporary layer TPL covering the first anode electrode AE1, the temporary layer TPL covering the second anode electrode AE2, and the temporary layer TPL covering the third anode electrode AE3 may be spaced apart from one another in the first direction DR1.

Subsequently, the method may include forming a second element insulating layer PDL2 on the temporary layer TPL and the first element insulating layer PDL1. The second element insulating layer PDL2 may be formed entirely on the temporary layer TPL and the first element insulating layer PDL1.

In step S100, the process of forming the second element insulating layer PDL2 may include a process of forming a film of at least one of the inorganic materials listed herein (e.g., a deposition process), and a process of patterning the inorganic material (e.g., an etching process).

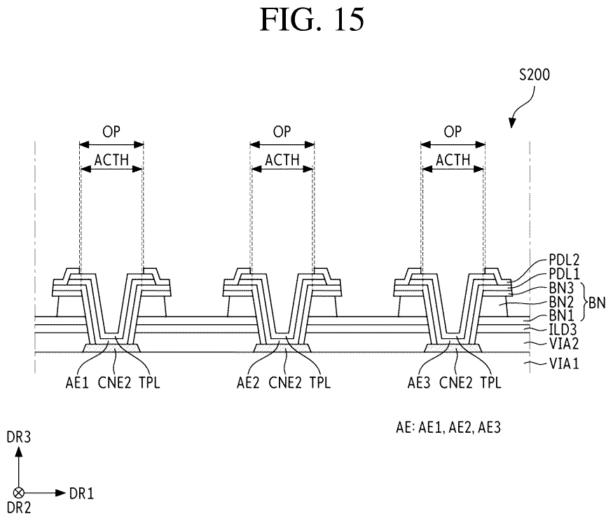

FIGS. 14 and 15 are cross-sectional views for illustrating step S200 of FIG. 10.

Referring to FIGS. 14 and 15, step S200 of forming an opening defined by an element insulating layer by performing a dry etching process will be described.

Initially, the method may include forming a plurality of photoresists PR is formed on the second element insulating layer PDL2, and then a dry etching process is conducted using the plurality of photoresists PR as a mask.

For example, the dry etching process may be conducted via a reactive ion etching (RIE) process using a reactive gas such as, for example, CHF₃, CH₃F, CH₂F₂, CHF₆, CF₄, C₂F₆ and C₃F₆, and sputtering gas such as, for example, Ar and O₂/Ar. In this instance, an inductively coupled plasma (ICP) source or a capacitively coupled plasma (CCP) source may be used as the plasma source.

In step S200, the second element insulating layer PDL2 located in the anode contact hole ACTH may be completely removed, and accordingly the temporary layer TPL may be exposed in the anode contact hole ACTH.

In step S200, since the temporary layer TPL works as an etch stopper for the dry etching process, the anode electrode AE may not be exposed and can be protected by the temporary layer TPL.

In step S200, the second element insulating layer PDL2 may define openings OP and expose the temporary layer TPL in the openings OP. The openings OP defined by the second element insulating layer PDL2 may define the emission areas EA (see FIGS. 4 to 9) of the display device 10.

In step S200, parts of the second bank layer BN2, the third bank layer BN3, the first element insulating layer PDL1, and the second element insulating layer PDL2 outside the anode contact hole ACTH may be removed. As a result, the first bank layer BN1 may be exposed.

In step S200, parts of the second bank layer BN2, the third bank layer BN3, the first element insulating layer PDL1, and the second element insulating layer PDL2 outside the anode contact hole ACTH may be removed isotropically.

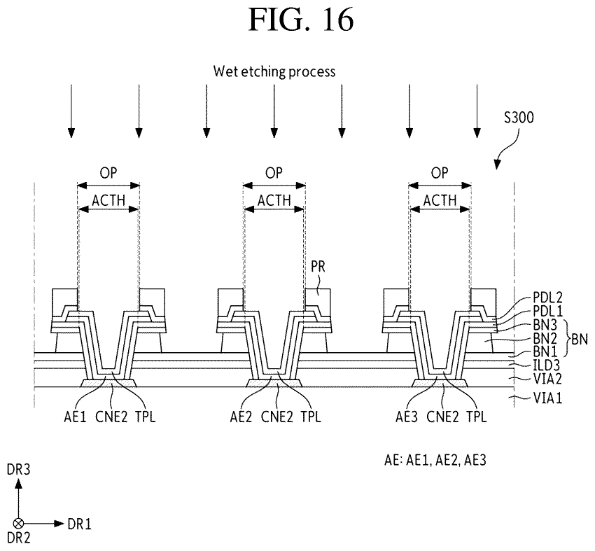

FIGS. 16 to 18 are cross-sectional views for illustrating step S300 of FIG. 10.

Hereinafter, step S300 of performing a wet etching process which removes a temporary layer and forms a tip of the bank structure will be described with reference to FIGS. 16 to 18.

Initially, the method may include forming a plurality of photoresists PR which entirely cover the upper surface of the second element insulating layer PDL2, and then conducting a dry etching process using the plurality of photoresists PR as a mask. In this process, the photoresists PR may not overlap with the openings OP or the anode contact holes ACTH.

For example, the wet etching process may be performed using a liquid chemical solution such as, for example, a hydrofluoric acid solution, a nitric acid solution, a tetramethylammonium hydroxide solution, and a potassium hydroxide solution.

In step S300, the second bank layer BN2 and the third bank layer BN3 including different metal materials may have different etch selectivities. Specifically, in the same etching process, the third bank layer BN3 may have higher etching resistance than the second bank layer BN2. In other words, in the same etching process, the second bank layer BN2 may include a material that has higher etch rate than the third bank layer BN3. Accordingly, the third bank layer BN3 may include a tip TIP that protrudes in the first direction DR1 more than the side surface 2c of the second bank layer BN2. The first element insulating layer PDL1 and the second element insulating layer PDL2 may overlap with the tip TIP of the third bank layer BN3 in the third direction DR3.

In step S300, the temporary layer TPL may be partially or completely removed depending on the required structure of the display device. The etching degree of the temporary layer TPL may be controlled by changing the process conditions of the wet etching process (e.g., the concentration of the etchant, the type of the etchant, or the process time).

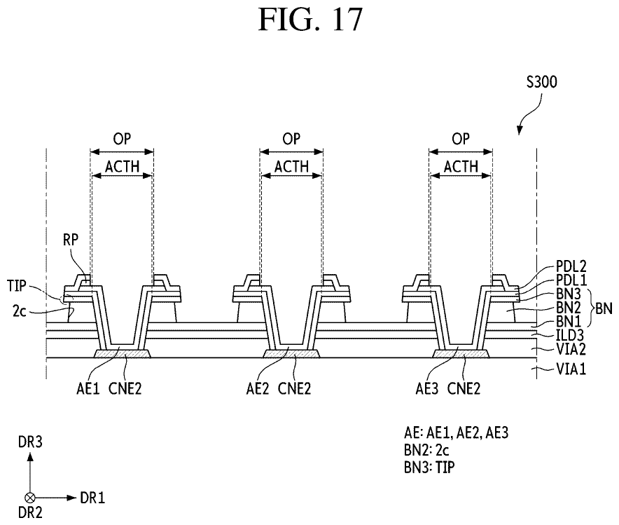

For example, in step S300, by removing the temporary layer TPL in the opening OP, a part of the temporary layer TPL may remain in the form of the residual pattern RP as illustrated in FIG. 17. As a result, the residual pattern RP may surround the opening OP, and the residual pattern RP may be formed between the anode electrode AE and the second element insulating layer PDL2 in the third direction DR3.

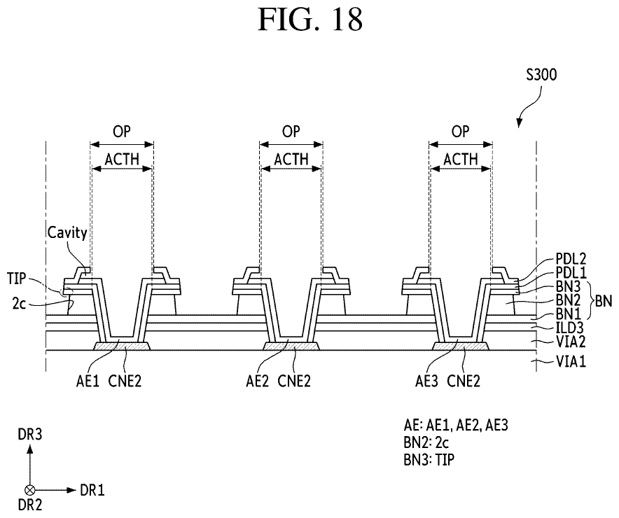

For example, in step S300, when the temporary layer TPL is completely removed, the temporary layer TPL may be completely removed, and a cavity may be formed between the anode electrode AE and the second element insulating layer PDL2 in the third direction DR3, as illustrated in FIG. 18. The cavity described herein may mean an empty space.

Hereinafter, a subsequent process will be described using the structure illustrated in FIG. 17 as an example. In some implementations, the structure illustrated in FIG. 18 may also include the same subsequent process.

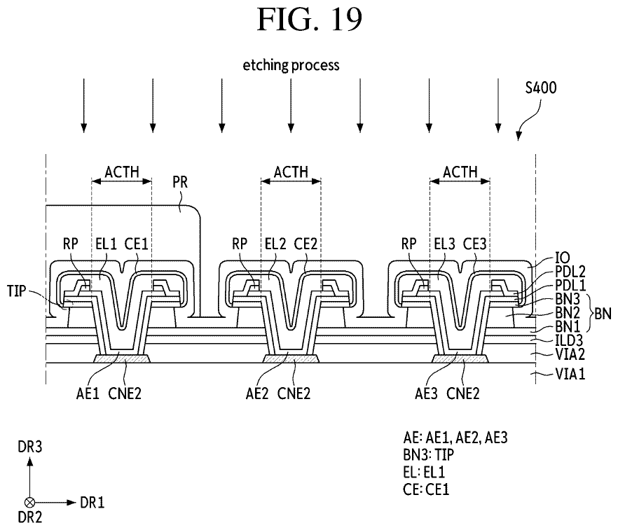

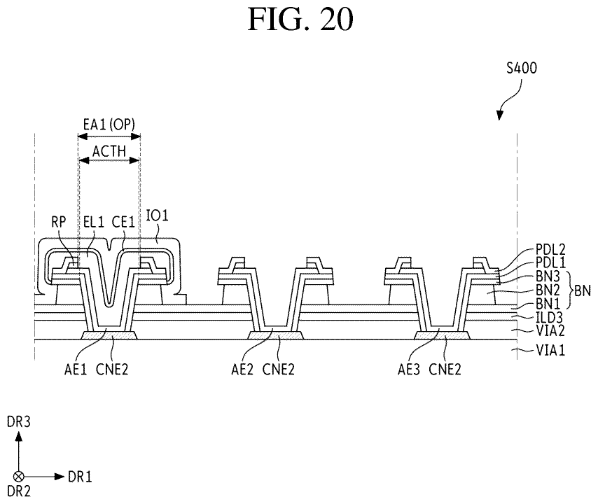

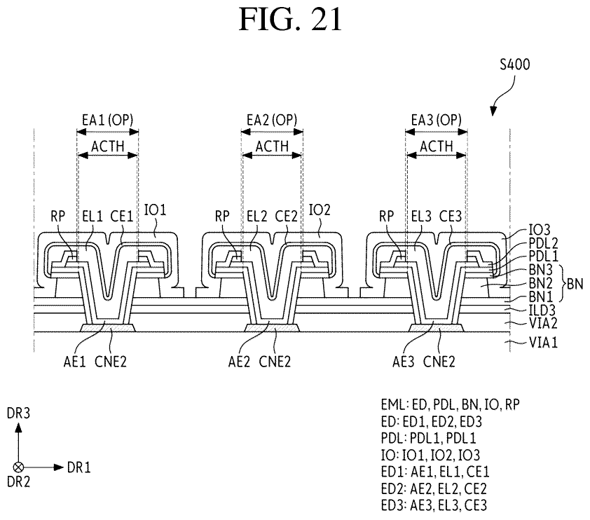

FIGS. 19 to 21 are cross-sectional views for illustrating step S400 of FIG. 10.

Referring to FIGS. 19 to 21, step S400 of forming an emissive layer, a cathode electrode, and an element inorganic layer on an anode electrode will be described.

Initially, a first emissive layer EL1 and a first cathode electrode CE1 are deposited on the first anode electrode AE1 to form a first light-emitting element ED1.

In step S400, the process of forming the first emissive layer EL1 may include a thermal deposition process. In step S400, the material for forming the first emissive layer EL1 may be formed not only on the first anode electrode AE1 but also on the second anode electrode AE2 and the third anode electrode AE3. Although not illustrated in the drawings, the material for forming the first emissive layer EL1 may be located also on the first bank layer BN1 in some implementations.

In the display device 10 according to embodiments of the present disclosure, since the third bank layer BN3 includes the tips TIP, the material for the first emissive layer EL1 formed on the first anode electrode AE1 may be spaced apart from the material for the first emissive layer EL1 formed on the second anode electrode AE2, the third anode electrode AE3, and the first bank layer BN1. In other words, since the third bank layer BN3 of the display device 10 includes the tips TIP, the emissive layer EL located separately on each of the first anode electrode AE1, the second anode electrode AE2, and the third anode electrode AE3 can be formed without a separate fine metal mask.

In step S400, the material for forming the first emissive layer EL1 may be in contact with the residual pattern RP. In an example in which the display device 30 includes the cavity of FIG. 18, the material for forming the first emissive layer EL1 may be deposited inside the cavity.

In step S400, the process of forming the first cathode electrode CE1 may include a thermal deposition process or a sputtering deposition process. The process of forming the first cathode electrode CE1 may have higher step coverage characteristics than the process of forming the first emissive layer EL1. Therefore, the first cathode electrode CE1 may entirely cover the first emissive layer EL1.

In step S400, the material for forming the first cathode electrode CE1 may be formed not only on the first anode electrode AE1 but also on the second anode electrode AE2 and the third anode electrode AE3. Although not illustrated in the drawings, the material for forming the first cathode electrode CE1 may be located also on the first bank layer BN1 in some implementations.

In the display device 10 according to embodiments of the present disclosure, since the third bank layer BN3 includes the tips TIP, the material for the first cathode electrode CE1 formed on the first anode electrode AE1 may be spaced apart from the material for the first cathode electrode CE1 formed on the second anode electrode AE2, the third anode electrode AE3 and the first bank layer BN1. In other words, since the third bank layer BN3 of the display device 10 includes the tips TIP, the cathode electrode CE located separately on each of the first anode electrode AE1, the second anode electrode AE2, and the third anode electrode AE3 can be formed without a separate fine metal mask.

In step S400, the material for forming the cathode electrode CE may come into contact with the tip of the third bank layer BN3. The redundant descriptions will be omitted.

Subsequently, the method may include forming the element inorganic layer IO. The element inorganic layer IO may cover the profile of the underlying structures with a uniform thickness, and the element inorganic layer IO may be formed entirely on the first anode electrode AE1, the second anode electrode AE2, and the third anode electrode AE3.

In step S400, the process of forming the element inorganic layer IO may include a process of forming a film of at least one of the inorganic materials listed herein (e.g., a deposition process), and a process of patterning the inorganic material (e.g., an etching process).

Subsequently, the method may include forming a photoresist PR on the first anode electrode AE1 and the periphery of the first anode electrode AE1, and performing an etching process using the photoresist PR as a mask.

In step S400, the method may include removing the material for forming the first emissive layer EL1, the material for forming the first cathode electrode CE1, and the material for forming the element inorganic layer IO not overlapping with the photoresists PR all at once. Accordingly, the second anode electrode AE2 and the third anode electrode AE3 may be exposed again, and the element inorganic layer IO may be formed in the form of the first element inorganic layer IO1.

In step S400, the first emissive layer EL1 may be entirely in contact with the anode electrode AE in the opening OP, and the first cathode electrode CE1 may be entirely in contact with the first emissive layer EL1 in the opening OP. Accordingly, a first emission area EA1 may be defined. Through step S400, a first light-emitting element ED1 in line with the first emission area EA1 can be formed.

Subsequently, the method may include repeating the same process described herein to form a second emissive layer EL2, a second cathode electrode CE2, and an element inorganic layer IO on the second anode electrode AE2. Through step S400, a second light-emitting element ED2 and a second element inorganic layer IO2 in line with the second emission area EA2 may be formed.

In some aspects, the method may include repeating the same process described herein to form a third emissive layer EL3, a third cathode electrode CE3 and an element inorganic layer IO3 on the third anode electrode AE3. Through step S400, a third light-emitting element ED3 and a third element inorganic layer IO3 in line with the third emission area EA2 may be formed.

In this manner, a display element layer EML overlapping with the anode contact hole ACTH illustrated in FIG. 7 may be formed. The redundant descriptions will be omitted.

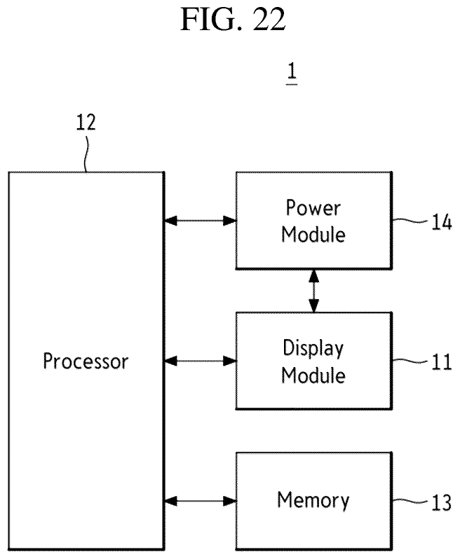

FIG. 22 is a block diagram of an electronic device according to an embodiment of the present disclosure.

Referring to FIG. 22 in conjunction with FIGS. 1 to 21, the display devices 10 and 30 according to the embodiments may be applied to a variety of electronic devices 1. The electronic device 1 according to the embodiment may include the display devices 10 and 30 described herein, and may further include a module or device having additional functions in addition to the display devices 10 and 30.

The electronic device 1 according to the embodiment may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 15 may store data information supportive of the operation of the processor 12 or the display module 11. In an example in which the processor 12 executes an application stored in the memory 15, an image data signal and/or an input control signal may be transmitted to the display module 11. The display module 11 may process the received signal and output image information through a display screen.

The power module 14 may include a power supply module such as, for example, a power adapter and a battery device, and a power conversion module that converts the power supplied by the power supply module to generate power for the operation of the electronic device 1.

At least one of the elements of the electronic device 1 described herein may be included in the display devices according to the embodiments described herein. In some aspects, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

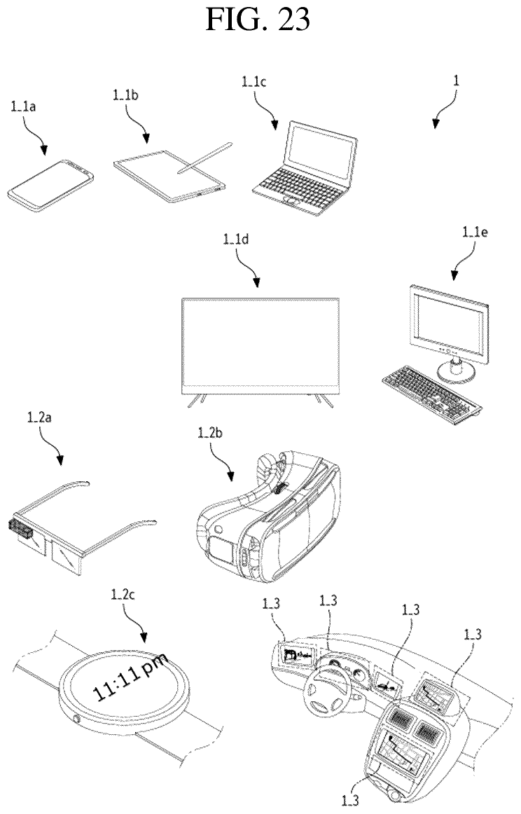

FIG. 23 is a view illustrating electronic devices according to a variety of embodiments of the present disclosure.

Referring to FIG. 23, a variety of electronic devices 1 employing the display devices 10 and 30 according to the embodiments may include not only image display electronic devices such as, for example, a smart phone 1_1a, a tablet PC 1_1b, a laptop computer 1_1c, a TV 1_1d and a desktop monitor 1_1e, but also wearable electronic devices including display modules such as, for example, smart glasses 1_2a, a head-mounted display 1_2b and a smart watch 1_2c, and electronic devices for vehicles 1_3 including display modules such as, for example, a center information display (CID) placed on the dashboard, the center fascia and the dashboard of a vehicle, and a room mirror display.

Embodiments of the disclosure should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including an emission area and a non-emission area;
a bank structure located on a surface of the substrate, overlapping with the emission area, and having an overhang structure;
a first element insulating layer disposed on the bank structure;
a first anode electrode disposed on the first element insulating layer; and
a second element insulating layer covering an edge of the first anode electrode, defining an opening, and in contact with the first element insulating layer,
wherein:
an upper surface of the first anode electrode is spaced apart from the second element insulating layer in the non-emission area, and
an undercut is formed between the first anode electrode and the second element insulating layer.

2. The display device of claim 1, wherein the bank structure comprises:
a first bank layer;
a second bank layer located on the first bank layer; and
a third bank layer having a tip protruding toward the non-emission area more than a side surface of the second bank layer.

3. The display device of claim 2, further comprising:
a first emissive layer disposed on the first anode electrode and entirely covering the second element insulating layer; and
a first cathode electrode disposed on the first emissive layer and in contact with the tip of the third bank layer.

4. The display device of claim 3, wherein the first cathode electrode is electrically connected to the second bank layer and the first bank layer through the third bank layer.

5. The display device of claim 3, further comprising a residual pattern which is located between the upper surface of the first anode electrode and the second element insulating layer in a direction perpendicular to the surface of the substrate in the non-emission area.

6. The display device of claim 5, wherein the residual pattern is in contact with the first anode electrode and the second element insulating layer.

7. The display device of claim 5, wherein the residual pattern is completely surrounded by the first emissive layer, the first anode electrode, and the second element insulating layer.

8. The display device of claim 5, wherein:
the residual pattern surrounds the opening, and
the residual pattern comprises a transparent metal material.

9. The display device of claim 5, further comprising:
a transistor disposed on the substrate; and
a connection electrode disposed on the transistor and electrically connected to the transistor,
wherein:
the first anode electrode and the connection electrode are in contact with each other in an anode contact hole penetrating the bank structure, and
the residual pattern surrounds the anode contact hole.

10. The display device of claim 3, further comprising a cavity which is formed between the upper surface of the first anode electrode and the second element insulating layer in a direction perpendicular to the surface of the substrate in the non-emission area.

11. A method for fabricating a display device, the method comprising:
forming an anode electrode, a temporary layer, and an element insulating layer on a substrate comprising a bank structure;
performing a dry etching process which forms an opening defined by the element insulating layer;
performing a wet etching process which removes the temporary layer and forms a tip of the bank structure; and
forming an emissive layer, a cathode electrode, and an element inorganic layer on the anode electrode.

12. The method of claim 11, wherein the performing the dry etching process which forms the opening defined by the element insulating layer comprises completely covering the anode electrode with the temporary layer in the opening.

13. The method of claim 12, wherein:
the performing the wet etching process which removes the temporary layer and forms the tip of the bank structure comprises completely removing the temporary layer in the opening,
wherein a part of the temporary layer outside the opening remains as a residual pattern between the anode electrode and the element insulating layer.

14. The method of claim 12, wherein:
the performing the wet etching process which removes the temporary layer and forms the tip of the bank structure comprises completely removing the temporary layer, and
a cavity is formed between the anode electrode and the element insulating layer outside the opening based on the performing the wet etching process.

15. An electronic device comprising:
at least one display device comprising a substrate comprising an emission area and a non-emission area; and
at least one of a display module, a processor, a memory, and a power module connected to the at least one display device,
wherein:
the at least one display device comprises:
a substrate comprising an emission area and a non-emission area;
a bank structure located on a surface of the substrate, overlapping with the emission area, and having an overhang structure;
a first element insulating layer disposed on the bank structure;
a first anode electrode disposed on the first element insulating layer; and
a second element insulating layer covering an edge of the first anode electrode, defining an opening, and in contact with the first element insulating layer,
wherein:
an upper surface of the first anode electrode is spaced apart from the second element insulating layer in the non-emission area, and
an undercut is formed between the first anode electrode and the second element insulating layer.

16. The electronic device of claim 15, wherein the bank structure comprises:
a first bank layer;
a second bank layer located on the first bank layer; and
a third bank layer having a tip protruding toward the non-emission area more than a side surface of the second bank layer.

17. The electronic device of claim 16, further comprising:
a first emissive layer disposed on the first anode electrode and entirely covering the second element insulating layer; and
a first cathode electrode disposed on the first emissive layer and in contact with the tip of the third bank layer.

18. The electronic device of claim 17, further comprising a residual pattern which is located between the upper surface of the first anode electrode and the second element insulating layer in a direction perpendicular to the surface of the substrate in the non-emission area.

19. The electronic device of claim 18, wherein:
the residual pattern surrounds the opening, and the residual pattern comprises a transparent metal material.

20. The electronic device of claim 19, wherein the residual pattern is in contact with the first emissive layer, the first anode electrode, and the second element insulating layer.
